(19) United States
(12) Patent Application Publication
(10) Pub. No.: US 2025/0067999 A1
(43) Pub. Date: Feb. 27, 2025

(54) SPECTACLE LENS WITH REDUCED FRICTION PROPERTIES, MEASUREMENT METHOD FOR DETERMINING THE SMOOTHNESS OF THE SPECTACLE LENS AND METHOD FOR PRODUCING THE SPECTACLE LENS

(71) Applicant: RODENSTOCK GMBH, Munich (DE)

(72) Inventors: Hermann BRUNNER, Wessling (DE); Yvonne GRAGE, Munich (DE); Arne URBAN, Munich (DE); Michael VÖGT, Gilching (DE); Markus GRAU, Ismaning (DE); Philipp MERKELBACH, Bernried (DE); Andreas KEIL, Muhldorg am Inn (DE)

(21) Appl. No.: 18/721,927

(22) PCT Filed: Dec. 20, 2022
(86) PCT No.: PCT/EP2022/087033

§ 371 Date: Jun. 20, 2024

(30) Foreign Application Priority Data
Dec. 21, 2021 (DE) 10 2021 134 053.5

(51) Int. Cl. G02C 7/02; C23C 14/24; G02B 27/00

(52) U.S. Cl. CPC G02C 7/02; G02B 27/0006; C23C 14/24

(57) ABSTRACT

The present invention relates to a spectacle lens having a substrate and a functional coating arranged as the outermost layer on the substrate, wherein the functional coating imparts to the spectacle lens a haptic smoothness coefficient HGK of at most 0.28, preferentially at most 0.25, and/or a haptic smoothness coefficient R_HGK of at most 0.85, preferentially at most 0.80. The present invention furthermore relates to a measurement method for determining the smoothness of a spectacle lens, which is expressed by the haptic smoothness coefficient HGK and/or the haptic smoothness coefficient R_HGK, as well as to a method for producing the spectacle lens.

The present invention relates to a spectacle lens having a substrate and a functional coating arranged as the outermost layer on the substrate, to a measurement method for determining the smoothness of the spectacle lens and to a method for producing the spectacle lens.

Spectacle lenses which may be coated with a plurality of different layers are known in the prior art. For instance, the spectacle lens may be protected against scratches by coating with a hard layer. A reduction of reflection may also be achieved by coating with an interference/antireflection layer. Lastly, coating with a functional coating, which is sometimes also referred to as a topcoat or cleancoat, is used to repel dirt and water drops. Starting from the surface of the spectacle lens, a typical layer structure has the layer sequence: hard layer, interference/antireflection layer and functional coating. The latter therefore represents the outermost coating layer. Each of the aforementioned coating layers may consist of a single layer or a layer system having a plurality of layers.

In order to be repellent in relation to dirt and water drops, the functional coating generally has both oleophobic and hydrophobic properties. One measure of this is the respective contact angle that a corresponding liquid forms on the surface of the spectacle lens. In this context, it is generally the case that the oleophobic and hydrophobic properties are commensurately more pronounced when the contact angle of the respective liquid on the surface of the spectacle lens is greater. Although spectacle lenses coated with a functional coating can be freed well in this way from dirt and water drops that would otherwise adhere to the surface of the spectacle lens, the spectacle lens nevertheless needs to be cleaned periodically, for example by polishing with a wiping article, for example a microfiber cloth or the like. If the spectacle lens is previously brought in contact with running water, such a wiping article is likewise needed in order to dry the spectacle lens. In the present case, the term polishing also includes such drying.

Fundamentally, sliding the wiping article over the surface of the spectacle lens requires a certain exertion of force, which moreover becomes greater when the wiping speed increases. If the force applied during the wiping is too low, the wiping article sticks on the spectacle lens. This may lead to the fingers slipping over the wiping article. This in turn impairs the polishing process. As a result, the surface of the spectacle lens no longer feels sufficiently smooth when polishing with the wiping article.

Under ideal conditions, an optimal polishing result is achieved by wiping once with a clean microfiber cloth over the surface of the spectacle lens, which is also referred to as a so-called “one wipe clean”. Nevertheless, most spectacle wearers make a plurality of alternating polishing strokes in the width direction of the spectacle lens, i.e. alternately from left to right or right to left, when polishing the spectacle lens. In this case, a spectacle lens whose surface does not feel sufficiently smooth is perceived as particularly problematic.

The approaches known in the prior art for coating a spectacle lens with a functional coating are typically aimed at improving the oleophobic and hydrophobic properties so as to make the surface of the spectacle lens even more repellent in relation to adhesions such as dirt and water drops. Accordingly, the focus when coating spectacle lenses has previously been on improving the dirt- and water-repellent properties of the spectacle lens, rather than for instance on particularly easy wiping with little exertion of force.

The object of the present invention is therefore to provide a spectacle lens coated with a functional coating, wherein the spectacle lens is intended to be coated in such a way that, besides the repellence of dirt and water drops, particularly easy wiping with little exertion of force is possible. The object of the present invention is furthermore to provide a measurement method for determining the smoothness of such a spectacle lens as well as a method for producing such a spectacle lens.

The aforementioned objects are achieved by a measurement method having the features of claim 1, by a spectacle lens having the features of claim 5, and by a method for producing a spectacle lens having the features of claim 12. Preferred embodiments are disclosed in the dependent claims.

According to a first aspect of the invention, a spectacle lens having a substrate and a functional coating arranged as the outermost layer on the substrate is provided, the spectacle lens according to the invention being distinguished in that the functional coating imparts to the spectacle lens a haptic smoothness coefficient HGK of at most 0.28, preferentially at most 0.25, and/or a haptic smoothness coefficient R_HGK of at most 0.85, preferentially at most 0.80.

Because of the functional coating, which is distinguished by a haptic smoothness coefficient HGK of at most 0.28, preferentially at most 0.25, and/or a haptic smoothness coefficient R_HGK of at most 0.85, preferentially at most 0.80, the spectacle lens according to the invention allows particularly easy wiping with little exertion of force. Moreover, the exertion of force becomes only slightly greater when the wiping speed increases. The surface of the spectacle lens according to the invention thus feels particularly smooth when wiping, which is in turn haptically perceived as very satisfying. It is therefore deemed to be of very high quality. Furthermore, the functional coating of the spectacle lens according to the invention has both oleophobic and hydrophobic properties, for which reason it moreover has excellent dirt and water repellence and therefore overall an excellent cleanability and handleability.

The spectacle lens according to the invention will be described in more detail below. The haptic smoothness coefficients HGK and R_HGK, as well as the way in which they are determined, will be explained in connection with the measurement method according to the invention for determining the smoothness of a spectacle lens.

The spectacle lens according to the invention has a substrate. The substrate of the spectacle lens according to the invention is not subject per se to any particular restrictions. In respect of its geometrical shape, for instance, the substrate may fundamentally be planoparallel, biconcave, planoconcave, convexoconcave, concavoconvex, planoconvex or biconvex. Typically, the front face of the substrate is convexly shaped while the rear face lying toward the eye is concavely shaped. In this case, the geometrical shape for spectacle lenses with a positive refractive power is referred to as concavoconvex, and for spectacle lenses with a negative refractive power as convexoconcave. As regards the geometrical shape, furthermore, substrates for varifocal lenses are also to be mentioned. These are also referred to in the prior art as progressive lenses.

In respect of the basic material, the substrate of the spectacle lens according to the invention is likewise not further restricted. For instance, the substrate may be made from mineral glass or plastic glass. Plastic glass has the advantage over mineral glass that it has a smaller thickness and therefore a lower weight, which leads to a more comfortable wearing sensation. Furthermore, spectacle lenses made from plastic glass have an increased breaking resistance. In the present case, for example, polythiourethane, polymethyl methacrylate, polycarbonate, polyacrylate or polydiethylene glycol bisallyl carbonate and combinations thereof may be envisioned as plastic materials, although in principle other transparent plastic materials may also be used.

The basic material of the substrate is in this case selected so that the spectacle lens typically has a refractive index in a range of from 1.45 to 1.90, particularly in a range of from 1.45 to 1.55, in a range of from 1.59 to 1.68 or in a range of from 1.73 to 1.75. Substrates made of standard glass with a refractive index of about 1.50, of high quality glass with a refractive index of about 1.60 or 1.67, or of premium glass with a refractive index of about 1.74 may therefore be used.

As mentioned in the introduction, a hard layer may initially be applied onto the substrate. This is expedient in particular when the substrate is made from plastic glass, since this is a comparatively soft material and the susceptibility of a spectacle lens made therefrom in relation to scratches is therefore higher than for mineral glass. The hard layer may have a single-layer or multilayer structure. Various materials and methods, which may be selected suitably by a person skilled in the art, may be used for producing the hard layer. A person skilled in the art will likewise select a suitable thickness for the hard layer. If the hard layer is a hard varnish, it may for example be applied onto the substrate by means of dip-, spray- or spin-coating methods. If the hard layer is an inorganic material, on the other hand, for instance a material based on quartz, it may be applied onto the substrate by means of physical or chemical vapor deposition.

In order to promote the adhesion of the hard layer, the substrate may be subjected beforehand to a priming treatment. For this purpose, the substrate may also be provided with a priming layer, also known as a primer layer, which is used to promote adhesion. Besides the adhesion strength of the coating, the priming layer, which is sometimes also referred to as a buffer varnish layer, may also increase the breaking resistance of the spectacle lens. The substrate may, for example, be provided with the priming layer by means of dip-, spray- or spin-coating methods.

An interference/antireflection layer may be applied onto the substrate with the optionally present priming layer and the optionally present hard layer. Like the hard layer, the interference/antireflection layer may also have a single-layer or multilayer structure. Such interference/antireflection layers constructed in one layer or multiple layers are known to a person skilled in the art, the number of layers fundamentally not being further restricted in the case of an interference/antireflection layer constructed in multiple layers. For an interference/antireflection layer constructed in multiple layers, the layer sequence is usually selected in such a way that a layer having a low refractive index with a particular thickness is adjacent to a layer having a high refractive index with a particular thickness. In other words, for such a structure it is preferred that layers having a low refractive index and layers having a high refractive index are applied in alternation. Corresponding materials and layer thicknesses for producing such a structure are known to a person skilled in the art. For instance, the interference/antireflection layer may consist of a sequence of various transparent materials, including for example SiO₂, SiO, Ta₂O₅, TiO₂, ZrO₂, Al₂O₃, Nd₂O₅, Pr₂O₃, PrTiO₃, La₂O₃, Nb₂O₅, Y₂O₃, HfO₂, InSn Oxid (ITO), Si₃N₄, MgO, MgF₂, CeO₂ and ZnS, without being limited thereto, however. Among these materials, at least some, for instance SiO₂, have a comparatively low refractive index, while others in turn, for instance Ta₂O₅, have a comparatively high refractive index. The respective layers of the interference/antireflection layer may likewise be applied by means of physical or chemical vapor deposition. Exemplary methods for application by means of physical vapor deposition are electron beam evaporation from a crucible, resistive evaporation from a boat and plasma enhancement during the evaporation, without being limited thereto, however. The substrate may be heated during the application of the interference/antireflection layer.

As mentioned in the introduction, a reduction of reflection may be achieved by coating with an interference/antireflection layer. Fundamentally, however, the substrate may also be optically coated in such a way that an increase of reflection takes place. By analogy, the term mirroring is used.

Besides the substrate with the priming layer optionally present thereon, the hard layer optionally present thereon and the interference/antireflection layer optionally present thereon, the spectacle lens according to the invention has a functional coating. This is arranged as the outermost layer on the substrate. The priming layer, the hard layer and the interference/antireflection layer, if respectively present, are accordingly arranged in the order specified starting from the surface of the substrate between the substrate and the functional coating.

The functional coating of the spectacle lens according to the invention has both oleophobic and hydrophobic properties, so that it allows repellence of both dirt and water drops on the surface of the spectacle lens. Insofar as the functional coating is distinguished by a haptic smoothness coefficient HGK of at most 0.28, preferentially at most 0.25, and/or a haptic smoothness coefficient R_HGK of at most 0.85, preferentially at most 0.80, it is not subject to any further particular restrictions. Typically, the functional coating is formed from a compound (1) comprising a perfluorinated hydrocarbon radical, which has one or more etheric oxygen atoms, and further comprising at least one silyl group, which may be substituted with one or more hydrolysable groups, with the proviso that the compound (1) contains at least two hydrolysable groups and is represented by the following formula (A):

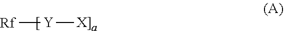

where a is 1 or 2, Rf denotes a perfluoroalkyl ether radical if a is 1, or a perfluoroalkylene ether radical if a is 2, X denotes a radical having at least one silyl group, which may be substituted with one or more hydrolysable groups, and Y denotes an optional radical which links the perfluoroalkyl(ene) ether radical Rf and the radical X to one another.

By the presence of at least two hydrolysable groups, in principle two-dimensional or three-dimensional linking of the compound (1) to one another and to the surface of the spectacle lens, a priming layer optionally applied thereon, a hard layer optionally applied thereon or an interference/antireflection layer optionally applied thereon is possible. Two-dimensional linking requires a compound (1) having two hydrolysable groups, while three-dimensional linking requires a compound (1) having at least three hydrolysable groups. The linking of the compound (1) takes place by a hydrolysis reaction of the hydrolysable groups in the presence of water, which is present in traces during the application of the functional coating, followed by a condensation reaction, a siloxane bond ultimately being formed. The compound (1) may, however, also be present per se, i.e. without entering into a hydrolysis reaction, in the functional coating. Accordingly, hydrolysable groups may also be present in the functional coating of the spectacle lens according to the invention. In other words, the functional coating of the spectacle lens according to the invention is formed or derived from the compound (1).

It is preferred for the compound (1) to contain at least three hydrolysable groups since in this way, as already mentioned, three-dimensional linking of the compound (1) may in principle take place. Fundamentally, the mechanical stability of the functional coating and therefore also its abrasion resistance or longevity are increased by three-dimensional linking. In respect of an upper limit, the number of hydrolysable groups is not further restricted.

The hydrolysable groups may respectively be selected independently of one another for instance from an alkoxy group having 1 to 10 carbon atoms, for example a methoxy group, an ethoxy group, a propoxy group or a butoxy group, an alkoxyalkoxy group having 2 to 10 carbon atoms, for example a methoxymethoxy group or a methoxyethoxy group, an alkenyloxy group having 2 to 10 carbon atoms, for example an isopropenoxy group, an acyloxy group having 1 to 10 carbon atoms, for example an acetyloxy group, an amino group or a halogen atom, for example a chlorine atom, a bromine atom or an iodine atom, without being limited thereto, however. Among these hydrolysable groups, a methoxy group, an ethoxy group, an isopropenoxy group and a chlorine atom are preferred.

If the hydrolysable group is for example a halogen atom, as a result of the hydrolysis reaction the respective hydrogen halide is liberated. In the case of an alkoxy group, the respective alcohol is liberated. The hydrolysable group is therefore liberated in its protonated form.

In the compound (1), all the hydrolysable groups may be identical. For example, the hydrolysable groups may in each case be a methoxy group or an ethoxy group. In the compound (1), the silyl groups may be fully substituted with hydrolysable groups, so that the compound (1) has for example trimethoxysilyl groups or triethoxysilyl groups, without being limited thereto, however. If there is no substitution with hydrolysable groups or the substitution is incomplete, the silyl groups typically still contain alkyl or alkenyl radicals having 1 to 3 carbon atoms, for instance methyl, ethyl, propyl or vinyl, without being limited thereto, however.

As regards the perfluorinated hydrocarbon radical, the compound (1) is not subject to any particular restrictions so long as the perfluorinated hydrocarbon radical has one or more etheric oxygen atoms. In the present case, an etheric oxygen atom is understood to mean an oxygen atom which gives rise to an ether functionality inside the perfluorinated hydrocarbon radical. In respect of an upper limit, the number of etheric oxygen atoms is not further restricted in the present case.

The number of carbon atoms in the perfluorinated hydrocarbon radical may be from 2 to 100, example from 2 to 50, from 5 to 50, from 5 to 25 or from 10 to 25, without being limited thereto, however. The perfluorinated hydrocarbon radical is saturated and accordingly contains no carbon-carbon multiple bonds. Likewise, the perfluorinated hydrocarbon radical is aliphatic and accordingly contains no aromatic units. The perfluorinated hydrocarbon radical may be branched or unbranched, an unbranched structure being preferred. It is likewise preferred for the perfluorinated hydrocarbon radical not to be cyclic.

The perfluorinated hydrocarbon radical, which has one or more etheric oxygen atoms, may for example comprise the structural unit —(CF₂)ₓ—O—(CF₂)_{y}—, where the indices x and y respectively denote the number of difluoromethylene units and therefore also the number of carbon atoms. In each case one silyl group, optionally substituted with one or more hydrolysable groups, may be bound to one or both of the outer difluoromethylene units. If a silyl group is bound to only one of the two outer difluoromethylene units, a fluorine atom is bound to the other of the two outer difluoromethylene units. In addition thereto, a fluorine atom of the two outer or of the inner difluoromethylene units may be replaced with a silyl group, optionally substituted with one or more hydrolysable groups. Further, another perfluorinated hydrocarbon radical of the aforementioned structural unit may be located between a difluoromethylene unit and a silyl group, which radical links the difluoromethylene unit and the silyl group. Further silyl groups, optionally substituted with one or more hydrolysable groups, may be bound to such a perfluorinated hydrocarbon radical.

The compound (1) may also comprise further structural units, so long as the compound (1) comprises a perfluorinated hydrocarbon radical, which has one or more etheric oxygen atoms, and further comprises at least one silyl group, which may be substituted with one or more hydrolysable groups, with the proviso that the compound (1) contains at least two hydrolysable groups and is represented by the following formula (A):

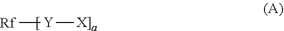

As already mentioned above, in formula (A) a is 1 or 2, Rf denotes a perfluoroalkyl ether radical if a is 1, or a perfluoroalkylene ether radical if a is 2, X denotes a radical having at least one silyl group, which may be substituted with one or more hydrolysable groups, and Y denotes an optional radical which links the perfluoroalkyl(ene) ether radical Rf and the radical X to one another.

Insofar as the compound (1) necessarily contains at least two hydrolysable groups, a must be 2 if the radical X in formula (A) contains only one silyl group, which is substituted with a single hydrolysable group.

As already generally mentioned above in connection with the compound (1), the perfluoroalkyl(ene) ether radical Rf contains no carbon-carbon multiple bonds and no aromatic units. Otherwise, the perfluoroalkyl(ene) ether radical Rf is not subject to any further restrictions.

The radical X in Formula (A) contains at least one silyl group, in which case each silyl group may be substituted with one or more hydrolysable groups. In the radical X, there are for example from 2 to 18, preferentially from 2 to 9 hydrolysable groups. If there are more than three hydrolysable groups, more than one silyl group is necessarily present in the radical X. Otherwise, the general comments above in connection with the compound (1) apply correspondingly in respect of the silyl groups and the hydrolysable groups.

The optional radical Y is a divalent radical and links the perfluoroalkyl(ene) ether radical Rf and the radical X to one another. The optional radical Y, if present, fundamentally has no hydrolysable groups. The optional radical Y may be an unsubstituted or substituted hydrocarbon radical. The optional radical Y may contain one or more structures selected from the group consisting of —NR(CO)—, —O(CO)—, —O— and —SiR₂—, where R represents an alkyl or alkenyl radical having 1 to 3 carbon atoms, for instance methyl, ethyl, propyl or vinyl, without being limited thereto, however. For example, the optional radical Y may be a hydrocarbon radical having in total 2 to 12 carbon atoms, in which case the hydrocarbon radical may contain one or more of the aforementioned structures.

Examples of the compound (1) which accord with formula (A) include trimethoxysilane, dimethoxysilane, triethoxysilane, triisopropenoxysilane, trichlorosilane and triaminosilane, each of these silanes comprising a perfluoroalkyl ether radical. In particular, the silane may be trimethoxysilane which comprises a perfluoroalkyl ether radical.

The functional coating is not necessarily formed from only one single compound (1). It may also be formed from various compounds (1). The formation of the functional coating may further involve a compound (2), which differs from the compound (1) merely in that the compound (2) contains only a single hydrolysable group. In this way, terminations of the two-dimensional or three-dimensional linking may be saturated since the compound (2) cannot enter into two-dimensional or three-dimensional linking because of the presence of only one hydrolysable group.

The functional coating may be applied onto the substrate with the priming layer optionally present thereon, the hard layer optionally present thereon and the interference/antireflection layer optionally present thereon, by means of suitable evaporation coating techniques, as described below in connection with the production method according to the invention.

In respect of the thickness, the functional coating of the spectacle lens according to the invention is not further restricted. For instance, the thickness of the functional coating may lie in a range of from 1 nm to 1000 nm. Preferentially, the thickness of the functional coating lies in a range of from 1 nm to 100 nm and even more preferentially in a range of from 1 nm to 20 nm. By way of example, a value of about 10 nm may be mentioned here for the thickness of the functional coating. The thickness of the functional coating, sometimes also referred to below as the physical layer thickness of the functional coating, may for example be adjusted by the duration of the evaporation and the evaporation coating rate.

Fundamentally, the above layers may be applied onto the substrate on one side or both sides, two-sided application at least of the functional coating on the front and rear faces of the substrate being preferred.

Because of the functional coating, which is typically formed from the compound (1), with the proviso that the compound (1) contains at least two hydrolysable groups and is represented by the formula (A) above, the surface of the spectacle lens according to the invention has a particularly low dynamic coefficient of friction. This may be regarded as a measure of the felt smoothness with which the surface of the spectacle lens is perceived. The dynamic coefficient of friction in this case relates to the friction force that needs to be overcome in order to perform a movement of the wiping article on the surface of the spectacle lens, for instance when polishing the spectacle lens with a microfiber cloth or the like.

Fundamentally, the dynamic coefficient of friction is dependent on the speed of the wiping movement. It is therefore sometimes also referred to as the speed-dependent dynamic coefficient of friction. Essentially, this means that the dynamic coefficient of friction would need to be determined continuously up to the maximum speed of the wiping movement in order to metrologically replicate the felt smoothness exactly. As has been discovered by the inventors, the metrological replication of the felt smoothness may however be significantly simplified, as explained below in connection with the measurement method according to the invention for determining the smoothness of a spectacle lens.

Thus, in a further aspect, the present invention relates to a measurement method for determining the smoothness of a spectacle lens with the aid of a rheometer by determining dynamic coefficients of friction in relation to a microfiber cloth, which describes a circular path around the center of the spectacle lens, the determination of dynamic coefficients of friction being carried out with speeds in the range of from 0.005 m/s to 0.4 m/s tangentially with respect to the described circular path and tangentially with respect to the surface of the spectacle lens, the measurement method according to the invention being one wherein the smoothness of the spectacle lens is expressed by a haptic smoothness coefficient HGK, calculated as a weighted average dynamic coefficient of friction from at least two dynamic coefficients of friction determined with different tangential speeds.

In the scope of the present invention, the movement for the metrological determination of the dynamic coefficient of friction describes a circular path around the center of the spectacle lens. The speed to which the dynamic coefficient of friction relates is tangential with respect to the described circular path and tangential with respect to the surface of the spectacle lens. It is therefore sometimes also referred to as the tangential speed. A range of from 0.005 m/s to 0.4 m/s is in this case to be regarded as relevant for the speed in practice, since the polishing of a spectacle lens is typically carried out with a speed in precisely this speed range. As it has been possible to establish by measurements, the maximum speed of the wiping movement typically has a value of 0.2 m/s.

For the determination of the dynamic coefficient of friction, a microfiber cloth of the type “Savina MX”, manufactured by “kbSeiren”, Osaka, Japan, with the following properties is used in the present case:
type of fiber: “BelimaX” ultrafine microfiber
composition: 70% polyester, 30% nylon
thickness: 0.32 mm
mass per unit area: 165 g/m²
number of longitudinal fibers per unit length: 78/2.54 cm
number of warp fibers per unit length: 81/2.54 cm

In this case, the microfiber cloth is wiped in a rotating movement around the center of the spectacle lens with the functional coating applied thereon. During the wiping with the microfiber cloth, it is necessary to ensure that no abrasive action that could modify its properties has been carried out beforehand on the surface of the spectacle lens. The pressure of the microfiber cloth onto the surface to be measured of the spectacle lens is applied by a resilient pin having an annular contact face, and is about 8380 N/m². For an inner radius of 17.5 mm and an outer radius of 20.5 mm of the annular contact face, this corresponds to a pressure force of 3 N. Viewed in cross section, the resilient pin has a rectangular shape with a height of 3 mm. The resilient pin is made of silicone and has a Shore A hardness of 40.

The microfiber cloth moves relative to the surface of the spectacle lens in the region of the annular contact face of the resilient pin. In order to take account of the speed dependency of the dynamic coefficient of friction, the dynamic coefficient of friction is expediently determined in the aforementioned speed range of from 0.005 m/s to 0.4 m/s, the speed meaning the tangential speed, as mentioned above. Starting from an initial value, the speed is increased in steps.

During the rotating movement of the microfiber cloth, the moment of force is ascertained with the aid of a rheometer. This is linked in the following way via the effective radius of the annular contact face of the resilient pin to the friction force that the microfiber cloth needs to overcome for a uniform movement relative to the surface of the spectacle lens:

$$moment of force = friction force \times effective radius \qquad ( I )$$

The effective radius may be approximated by the average radius. This corresponds to the average radius of the annular contact face of the resilient pin, and may be calculated as follows:

$$average radius = \frac{outer radius + inner radius}{2} \qquad ( II )$$

The dynamic coefficient of friction, abbreviated as μ_{d}, is in turn linked in the following way via the effective radius and the pressure force to the moment of force:

$${μ}_{d} = \frac{moment of force}{effective radius \times pressure force} = \frac{friction force}{pressure force} \qquad ( III )$$

For each speed v, an individual moment of force(v) due to an individual friction force(v) is obtained, and therefore so is an individual dynamic coefficient of friction(v), abbreviated as μ_{d}(v):

$${μ}_{d} ( v ) = \frac{moment of force ( v )}{effective radius \times pressure force} = \frac{friction force ( v )}{pressure force} \qquad ( IV )$$

In order to metrologically replicate the felt smoothness, the way in which the speed v is distributed as a function of the distance s over the surface of the spectacle lens over the time t for a polishing stroke is crucial. Experiments using a camera with a high frame rate show that, for a polishing stroke, the speed distribution along the distance that the wiping article covers in this case may be approximated very well with a harmonic oscillation, the wiping article coming to a stop at the turning points. Because of the symmetry of the wiping movement as a harmonic oscillation, it is sufficient to consider the speed distribution merely for ¼ of the polishing stroke, i.e. from the center of the spectacle lens with the position s=0 at the time t=0, where the wiping movement reaches its maximum speed vₘₐₓ, to the turning point with the position s=sₘₐₓ at the time t=T/4, where the wiping movement comes to a stop. T in this case denotes the duration of an entire polishing stroke, corresponding to a complete oscillation period. For the distance of ¼ of a polishing stroke as a function of time, the following relationship applies:

$$s ( t ) = {s}_{max} \times sin ( 2 π / T \times t ) = {s}_{max} \times sin ( ω \times t ) with t ∈ [ 0 ; T / 4 ] \qquad ( V )$$

Rearrangement as a function of time gives the following expression:

$$t ( s ) = 1 / ω \times arcsin ( s / {s}_{max} ) with s ∈ [ 0 ; {s}_{max} ] \qquad ( VI )$$

If the time derivative of the distance is taken, the speed is obtained as a function of time:

$$v ( t ) = ds ( t ) / dt = {s}_{max} \times cos ( ω \times t ) \times ω = {v}_{max} \times cos ( ω ) \times t ) \qquad ( VII )$$

By substituting the time with the expression above, the speed as a function of the distance is finally obtained:

$$v ( s ) = {v}_{max} \times cos ( arcsin ( s / {s}_{max} ) ) = {v}_{max} \times \sqrt{1 - {( s / {s}_{max} )}^{2}} \qquad ( VIII )$$

The speed as a function of the distance is illustrated in FIG. 1 for ¼ of a polishing stroke. The curve which describes the speed may be subdivided into three sections. These may in turn be represented as bars, the area of which respectively corresponds to the area under the associated curve section. As may be seen from the representation, 50% of the distance is covered with an average speed of 95% of the maximum speed. A further 35% of the distance is covered with an average speed of 72% of the maximum speed. The remaining 15% of the distance is covered with an average speed of 35% of the maximum speed. A correspondingly weighted average dynamic coefficient of friction may be specified on the basis of the weighting of the three speeds along the distance (50% of the distance with 95% vₘₐₓ, 35% of the distance with 72% vₘₐₓ and 15% of the distance with 35% vₘₐₓ). The weighted average dynamic coefficient of friction, abbreviated as μ̅_{d}, which is a measure of the felt smoothness, is in this case given as follows:

$${\overline{μ}}_{d} = 0.5 \times {μ}_{d} ( 95 \% {v}_{max} ) + 0.35 \times {μ}_{d} ( 72 \% {v}_{max} ) + 0.15 \times {μ}_{d} ( 35 \% {v}_{max} ) \qquad ( IX )$$

Using a value of 0.2 m/s for vₘₐₓ, as is typical of the maximum speed of the wiping movement, the following is obtained for the weighted average dynamic coefficient of friction:

$${\overline{μ}}_{d} = 0.5 \times {μ}_{d} ( 0.2 m / s ) + 0.35 \times {μ}_{d} ( 0.15 m / s ) + 0.15 \times {μ}_{d} ( 0.07 m / s ) \qquad ( X )$$

The weighted average dynamic coefficient of friction, since it is a measure of the felt smoothness, is also referred to as the haptic smoothness coefficient HGK. Correspondingly:

$$HGK \begin{matrix}= 0.50 \times {μ}_{d} ( 0.2 m / s ) + 0.35 \times {μ}_{d} ( 0.15 m / s ) + 0.15 \times {μ}_{d} ( 0.07 m / s ) & ( XI )\end{matrix}$$

The lower the haptic smoothness coefficient HGK is, the greater the felt smoothness of the surface of the spectacle lens is. Metrologically, the haptic smoothness coefficient thus corresponds to the weighted average dynamic coefficient of friction which is ascertained under special parameters, for instance in respect of the microfiber cloth used and the measurement geometry, as explained above. Surprisingly, merely determining the dynamic coefficient friction with three tangential speeds, namely 0.20 m/s, 0.15 m/s and 0.07 m/s, is sufficient in order to metrologically replicate the felt smoothness with sufficient accuracy.

With the haptic smoothness coefficient HGK, the felt smoothness may be metrologically replicated with sufficient accuracy. The smoothness sensorially experienced with the finger may be metrologically replicated even better if the acceleration phase in the vicinity of the turning point is also taken into consideration. For this purpose, a dynamic coefficient of friction which is determined with a comparatively low speed is additionally taken into account. A very good comparability between empirical tests of the smoothness and the description of the smoothness by means of friction curves is achieved if the dynamic coefficient of friction is determined with a tangential speed of 0.01 m/s, which is close to stopping, and added while multiplying by a weighting factor of 3 to the haptic smoothness coefficient HGK. The haptic smoothness coefficient R_HGK obtained in this way then reads:

$$R\_HGK = HGK + 3 \times {μ}_{d} ( 0.01 m / s ) \qquad ( XII )$$

As mentioned in the introduction, the functional coating imparts to the spectacle lens according to the invention a haptic smoothness coefficient HGK of at most 0.28, preferentially at most 0.25, and/or a haptic smoothness coefficient R_HGK of at most 0.85, preferentially at most 0.80.

The measurement method according to the invention is fundamentally not restricted to determining the smoothness of a spectacle lens. It may fundamentally be applied to any type of coated or uncoated surface. With the aid of the two haptic smoothness coefficients HGK and R_HGK, different surface coatings may be for example discriminated and objectively assessed in their quality. In this way, limit values for different quality categories may be defined.

In a further aspect, the present invention in turn relates to a method for producing a spectacle lens, in particular for producing the spectacle lens according to the invention, comprising the following steps (a) to (f):
(a) adjusting coating parameters on a coating apparatus,
(b) providing a substrate,
(c) inserting the substrate into the coating apparatus,
(d) providing the substrate with a functional coating in the coating apparatus, so that a spectacle lens having a substrate and a functional coating arranged as the outermost layer on the substrate is obtained,
(e) removing the spectacle lens from the coating apparatus, and
(f) determining the haptic smoothness coefficient HGK and/or the haptic smoothness coefficient R_HGK in accordance with the measurement method according to the invention, as described above.

With the production method according to the invention, which will be described in more detail below with reference to the flowchart of FIG. 2, the spectacle lens according to the invention as described above may be obtained in an optimized way.

In step (a) of the production method according to the invention, coating parameters are adjusted on a coating apparatus (S100).

In this case, the coating apparatus is configured in such a way that at least one substrate can be provided with a functional coating therein. For reasons of economy, however, it is preferred that a multiplicity of substrates can be provided simultaneously with a functional coating in the coating apparatus, so as in this way to minimize unit costs. Although one substrate is referred to below, the following comments apply equally for a multiplicity of substrates.

FIG. 3 schematically represents a coating apparatus 10 with an associated control unit 2, such as may be used in the production method according to the invention. The control unit is used to operate the coating apparatus and therefore also to adjust the coating parameters. Typically, the control unit has at least an arithmetic unit 20, a memory unit 22, a communication unit 24 and an input unit 26. In one preferred embodiment, the control unit is a computer.

The adjustment of the coating parameters on the coating apparatus is carried out such that the coating apparatus is put into a state for carrying out a coating process, i.e. for providing a substrate with a functional coating. By means of the control unit, corresponding coating parameters are accordingly adjusted on the coating apparatus, for example electrical variables, for instance electrical currents and voltages for operating an emission device 12 of the coating apparatus. The emission device is suitable for evaporating a coating material, which is used to apply the functional coating onto the substrate. As shown in FIG. 3, the emission device is connected to the control unit via a connection 42′ which is suitable for transmitting control instructions. The values to be adjusted in this case are naturally dependent not only on the type of emission device but also on the type of coating material used. Typical adjustment values for the evaporation of a coating material are adequately known to the person skilled in the art.

The coating apparatus is preferentially a vacuum coating apparatus, which is understood to mean that the application of the functional coating onto the substrate takes place in a vacuum chamber under vacuum conditions. It is moreover preferable for the emission device of the coating apparatus to be a thermal evaporator. By applying an electrical current, thermal energy that makes it possible to evaporate the coating material is released at the ohmic resistance of the thermal evaporator. The vapor of the coating material which is formed is then deposited as a coat substantially uniformly in the coating apparatus, and therefore also on the substrate.

Further coating parameters which may be adjusted are, for example, a termination condition. This is intended to mean a condition upon the occurrence of which the coating apparatus ends the coating process, which is intended in particular to mean a time duration or a physical layer thickness to be achieved of the functional coating.

In step (b) of the production method according to the invention, a substrate is provided (S102). As already mentioned in more detail above, the substrate per se is not subject to any particular restrictions. The comments above that have been made in this regard in connection with the spectacle lens according to the invention therefore apply correspondingly for the production method according to the invention.

For the sake of completeness, it should be noted that step (b) may also be carried out before step (a).

In step (c) of the production method according to the invention, the substrate is inserted into the coating apparatus (S104). For example, the substrate to be provided with a functional coating may be positioned in the coating apparatus with holding elements intended therefor of a holding device 18. As shown in FIG. 3, a multiplicity of substrates 30 to be provided with a functional coating may be arranged on the holding device of the coating apparatus.

Before the substrate is inserted into the coating apparatus, a priming layer, a hard layer and an interference/antireflection layer may be applied to the substrate in the order specified. Here again, the comments above that have been made in this regard in connection with the spectacle lens according to the invention apply correspondingly.

While the application of the hard layer, for example by means of dip-, spray- or spin-coating methods, takes place in a device intended specifically therefor, the application of the interference/antireflection layer may take place in the coating apparatus as is used for the application of the functional coating onto the substrate.

In step (d) of the production method according to the invention, the substrate is provided with a functional coating in the coating apparatus, so that a spectacle lens having a substrate and a functional coating arranged as the outermost layer on the substrate is obtained (S106). As already mentioned above, the coating apparatus is preferentially a vacuum coating apparatus. Accordingly, the application of the functional layer preferentially takes place in a vacuum chamber under vacuum conditions, the coating material being deposited as a vacuum coat while forming the functional coating on the substrate. The pressure prevailing in the vacuum chamber during the coating process is typically less than 10⁻² mbar.

In one preferred embodiment, the coating apparatus has a shutter device 14 in order to interrupt the material flow of the coating material from the emission device to the substrate arranged on the holding device when required. Advantageously, the coating process may in this way be ended with a minimal time delay when the physical layer thickness to be achieved of the functional coating has been reached. In contrast thereto, reducing the thermal energy supply, for example by reducing the electrical current applied to the thermal evaporator, would entail a longer time delay since that electrical current would correspondingly need to be stepped down to such an extent that evaporation of the coating material can no longer take place, coating material continuing to be evaporated during the stepping down.

As shown in FIG. 3, the shutter device is connected to the control unit by means of a connection 42 which is suitable for transmitting control instructions. It is preferred for the coating apparatus additionally to have a measurement sensor 16 that is connected to the control unit by means of a connection 40 which is suitable for transmitting measurement data. The connections 40, 42, 42′ may be configured according to choice as cabled or advantageously wireless.

In one preferred embodiment, the measurement sensor is a quartz resonator. Via the change in its natural frequency, with a known area of the quartz resonator, the mass increase of the functional coating may be converted into a physical layer thickness while taking its density into account. In this way, the increase of the physical layer thickness due to the vapor coat may be monitored. As soon as the physical layer thickness to be achieved has been reached as a termination condition, the coating process is ended with the aid of the shutter device, which is typically done by covering the emission device.

Alternatively, embodiments may also be envisioned in which the measurement sensor merely monitors the progressive duration of the coating and, after a time duration previously adjusted as a termination condition in the coating parameters has elapsed, ends the coating process. In such a case, the measurement sensor may also be entirely obviated.

In order to obtain a spectacle lens having a substrate and a functional coating arranged as the outermost layer on the substrate, it is preferred for the substrate to be provided with a functional coating in the coating apparatus in step (d) by evaporation using a source containing the compound (1). The compound (1) used as the coating material is in this case evaporated, optionally together with a further compound, for example the compound (2). The vapor formed in this way from the compound (1) and optionally further compounds moves in the direction of the substrate and is deposited on the surface of the substrate by condensation while forming the functional coating. By analogy, this is also referred to as vapor deposition of the compound (1). For the sake of simplicity, only the compound (1) is referred to here, although this is not intended to exclude the presence of a further compound, for instance the compound (2).

Evaporation coating is a high vacuum-based coating technique and is included among the methods of physical vapor deposition. Typical process pressures lie in a range of from 10⁻⁷ to 10⁻⁴ mbar. The starting material to be evaporated is in this case heated to temperatures close to the boiling point. By the presence of water in the vacuum chamber, which is present in small amounts during or after the coating, a hydrolysis reaction of the hydrolysable groups may take place, followed by a condensation reaction, so that in principle two-dimensional or three-dimensional linking of the evaporation coated compound (1) may take place.

The source containing the compound (1) is preferably a tablet or pellet, which contains the compound (1) in bound form. Tablets which may be used in the present case may, for example, be formed from a ceramic base body that has a high ratio of surface area to volume. Pellets which may be used in the present case may, for example, be formed from copper crucibles that are filled with steel wool. The ceramic base body, or the steel wool, is in this case impregnated with the starting material to be evaporated. Corresponding tablets or pallets are commercially available. By introducing such a pellet or tablet into a compartment intended therefor of the emission device, the coating material, which is then deposited as a vapor coat on the surface of the substrate, may be made to evaporate by the thermal energy supply.

If required, the surface to be coated of the substrate may be subjected to a plasma treatment beforehand.

The temperature during the evaporation is selected so that on the one hand sufficient release of the coating material to be evaporated takes place, but on the other hand it is not broken down. The evaporation is typically carried out with an evaporation rate in a range of from 0.05 nm/s to 3 nm/s, a range of from 0.1 nm/s to 1 nm/s being preferred, and a range of from 0.25 nm/s to 0.45 nm/s being even more preferred, for the maximum evaporation rate. The evaporation rate is understood to mean the rate at which the coating material is evaporation coated onto the substrate, for which reason it is also referred to as the evaporation coating rate. The evaporation coating rate depends inter alia on the evaporation temperature of the coating material. Together with the duration of the evaporation, the physical layer thickness of the functional layer to be applied onto the substrate may be adjusted by the selection of the evaporation rate.

As already mentioned above, the evaporation is preferably carried out with the aid of a thermal evaporator, for example with the aid of a resistive evaporator. The energy required therefor is in this case input by heating the compartment of the emission device, which is for example a material container. The tablet or pellet that contains the compound (1) in bound form may be located therein. The material container may be a boat made of molybdenum, tungsten or tantalum, or alternatively a boat made of ceramic materials. Typically, the boat current lies in a range of from 0.1 A to 10 A, a range of from 1.0 A to 7.0 A being preferred, and a range of from 3.0 A to 6.0 A being even more preferred. The thermal evaporator is operated with an AC voltage of 230 V. The theoretical power consumption of the thermal evaporator may be calculated as follows:

$$theoretical power consumption = \sqrt{2} \times 230 V \times boat current \qquad ( XIII )$$

Alternatively, the evaporation may also be carried out by means of electron beams, arc discharges or lasers.

In step (e) of the production method according to the invention, the spectacle lens is removed from the coating apparatus (S108). If the coating process has taken place in a vacuum chamber, the coating apparatus is first brought to atmospheric pressure conditions, which may for example be carried out by introducing an inert gas.

In step (f) of the production method according to the invention, the haptic smoothness coefficient HGK and/or the haptic smoothness coefficient R_HGK is or are determined (S110). This is carried out in accordance with the measurement method according to the invention, as described above.

The functional coating applied onto the substrate does not require any special subsequent processing. The spectacle lens which may be obtained by the production method according to the invention may therefore be used directly for manufacturing spectacles.

If required, however, the production method according to the invention may comprise the following step (g) after step (f):
(g) ascertaining a deviation of the haptic smoothness coefficient HGK and/or of the haptic smoothness coefficient R_HGK from a previously established setpoint value, in order to adapt the coating parameters in step (a) on the basis of the ascertained deviation if appropriate (S112).

A setpoint value of the haptic smoothness coefficient HGK and/or of the haptic smoothness coefficient R_HGK may be established beforehand as a function of the required quality category. The actual value obtained in step (f) for the smoothness of the spectacle lens, expressed by the haptic smoothness coefficient HGK and/or the haptic smoothness coefficient R_HGK, may then be compared with the previously established setpoint value. Subsequently, on the basis of the ascertained deviation, it is checked whether or not the quality requirements for the smoothness of the spectacle lens are fulfilled. If the ascertained deviation is too great, i.e. the quality requirements are not fulfilled, the coating parameters are adapted with the aim of reducing the deviation in the next method cycle so that the spectacle lens obtained in the next method cycle satisfies the quality requirements. Preferably, such adaptation of the coating parameters is intended to mean an adaptation of the termination condition, in particular an adaptation of the physical layer thickness to be achieved of the functional coating.

As is known to the person skilled in the art, the smoothness of the spectacle lens increases with an increasing physical layer thickness of the functional coating. The smoothness of the spectacle lens may accordingly be controlled by the selection of the physical layer thickness as a termination condition. Other coating parameters may, however, also be adapted in order to take account of an excessive deviation, if there is one. For instance, it is fundamentally also conceivable that, in the case of a thermal evaporator as the emission device, the electrical current applied to the thermal evaporator is correspondingly adapted.

The adaptation of the coating parameters represents an optimization loop. Starting from the ascertained deviation, the coating parameters are adapted with the aim of achieving a desired quality category in the next method cycle. In the optimal case, the ascertained deviation in the next method cycle is so small that further adaptation of the coating parameters is no longer necessary.

The present invention makes it possible to provide a spectacle lens having reduced friction properties. This is achieved by a functional coating that has a haptic smoothness coefficient HGK of at most 0.28, preferentially at most 0.25, and/or a haptic smoothness coefficient R_HGK of at most 0.85, preferentially at most 0.80, in which case the measurement method according to the invention for determining the smoothness of a spectacle lens may be used in order to determine the haptic smoothness coefficients HGK and R_HGK.

Because of the oleophobic and hydrophobic properties of the functional coating, the spectacle lens according to the invention, which may be obtained by the production method according to the invention, moreover has an excellent dirt and water repellence and therefore overall an excellent cleanability and handleability.

### DESCRIPTION OF THE FIGURES

FIG. 1 shows a graphical representation of the relationship between speed and distance during the wiping movement over a spectacle lens for ¼ of a polishing stroke. In comparison with the curve on the left side, three bars have additionally been introduced on the right side, the area of which respectively corresponds to the area under the associated curve section.

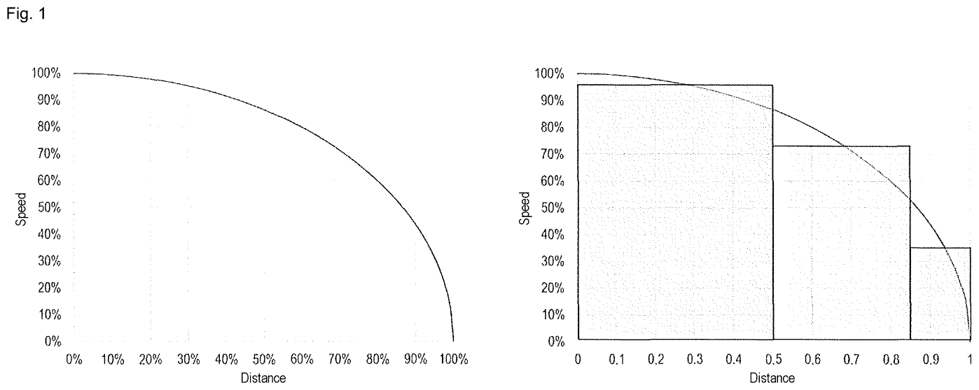

FIG. 2 shows the production method according to the invention in the form of a flowchart.

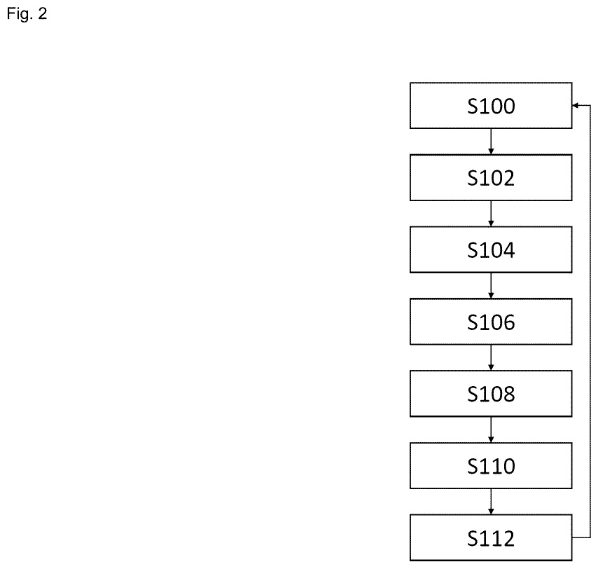

FIG. 3 shows a schematic representation of a coating apparatus with an associated control unit for providing a substrate with a functional coating, such as may be used in the production method according to the invention.

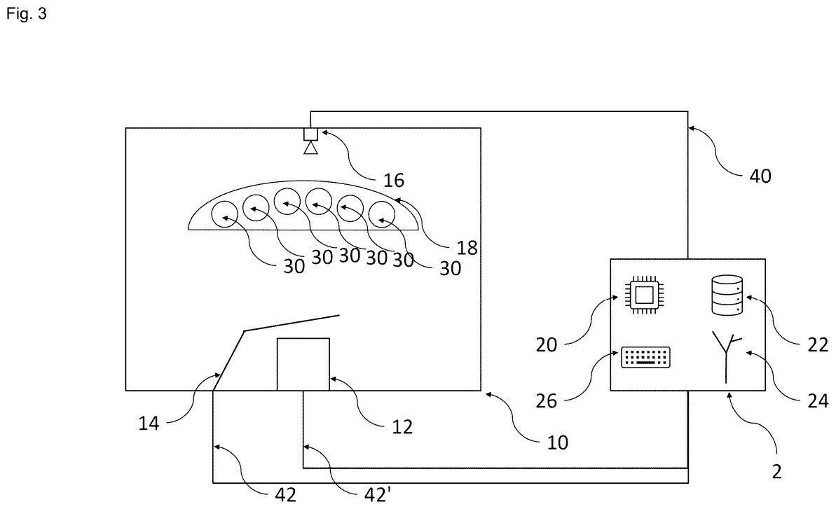

FIG. 4 shows the dynamic coefficient of friction as a function of the wiping speed for the coated plastic spectacle lenses of the exemplary embodiment and of the comparative example. The curves were obtained by determining the dynamic coefficients of friction with tangential speeds of 0.0002 m/s, 0.002 m/s, 0.01 m/s, 0.03 m/s, 0.07 m/s, 0.15 m/s, 0.20 m/s and 0.40 m/s, and subsequent interpolation with the aid of the dynamic coefficients of friction determined with these speeds. The points (0.01 m/s, 0.07 m/s, 0.15 m/s and 0.20 m/s) relevant for the calculation are denoted by markings.

### EXAMPLES

The following exemplary embodiment serves to further explain the present invention, without being limited thereto, however.

A cylindrically round plastic spectacle lens having the following properties was used as the substrate for the coating:
diameter: 60 mm
refractive index: 1.60
refracting power (spherical effect): −2.25 dpt

With the aid of a dip method, a hard layer was first of all applied onto the substrate. An interference/antireflection layer was in turn applied thereon with the aid of an ion-enhanced physical vapor deposition method. After having applied the last layer of the interference/antireflection layer, the surface was subjected to a plasma treatment before the functional coating was evaporation coated thereon. For this purpose, a pellet of the “Surfclear 100M” type, which contained a coating material that accords with formula (A) in bound form, was heated in a vacuum coating apparatus by a resistive evaporator with a boat current of 5.4 A. A functional coating having a thickness of 9 nm was in this case formed on the interference/antireflection layer. The maximum evaporation coating rate was 0.44 nm/s, with a coating time of 50 seconds. After the application of the functional coating, the coating process was ended and the vacuum coating apparatus was opened to the atmosphere.

After the coating, the spectacle lens obtained in this way was subjected to no further treatment, in particular no abrasive action, extending beyond conventional cleaning by wiping.

The spectacle lens was then measured in respect of its smoothness in accordance with the measurement method according to the invention. For this purpose, the spectacle lens was first fixed by means of a holder in a rheometer of the “Haake Mars iQ Air” type, centrally on the lower support of the measuring device, so that the functional coating which was applied on the convex side of the substrate faced in the direction of the rotor of the measuring device. The middle of the spectacle lens lay exactly below the center of the rotor. A microfiber cloth of the type “Savina MX”, manufactured by “kbSeiren”, Osaka, Japan, with dimensions of 45 mm×45 mm, was then placed on the surface of the spectacle lens. The rotor of the measuring device was configured in such a way that there was a circular plate on its lower end, on which a silicone ring having an inner radius of 17.5 mm, an outer radius of 20.5 mm and a height of 3 mm was in turn applied centrally. The silicone ring had a Shore A hardness of 40.

In order to measure the dynamic coefficient of friction, the rotor was lowered onto the convex side of the spectacle lens. With the aid of the silicone ring of the rotor, the microfiber cloth was pressed vertically onto the surface of the spectacle lens with a pressure force of 3 N. By rotating the rotor, the microfiber cloth was moved uniformly relative to the surface of the spectacle lens for a particular time duration, which corresponded to four revolutions of the microfiber cloth on the surface of the spectacle lens, this taking place with a speed of 0.01 m/s tangentially with respect to the outer radius of the silicone ring. The measuring device was simultaneously used to ascertain the moment of force which was required to move the microfiber cloth relative to the surface of the spectacle lens. This finally enabled the dynamic coefficient of friction for the tangential speed of 0.01 m/s to be determined. The determination of the dynamic coefficient of friction for the tangential speeds of 0.07 m/s, 0.15 m/s and 0.20 m/s was carried out in a similar way to this. The number of revolutions was in this case adapted to the respective speed while taking into account an acceleration phase in order to achieve a uniform speed, and was between four and eight revolutions.

The dynamic coefficients of friction determined in this way gave an HGK of 0.287 according to formula (XI) and an R_HGK of 0.614 according to formula (XII).

In order to achieve a higher quality category in the next method cycle, particularly in respect of the HGK of 0.287, an adaptation of the coating parameters was carried out. In the present case, the coating parameters were adapted by adjusting a physical layer thickness to be achieved of the functional coating, as the termination condition, of 13 nm with a maximum evaporation coating rate of 0.43 nm/s and a coating time of 68 seconds.

An identical substrate was subsequently provided with a functional coating in the vacuum coating apparatus using the adapted coating parameters. The dynamic coefficients of friction were determined as before.

The dynamic coefficients of friction determined this way gave an HGK of 0.24 according to formula (XI) and an R_HGK of 0.50 according to formula (XII).

By the adaptation of the coating parameters which was carried out, it was possible to reduce the haptic coefficients of friction HGK and R_HGK. Correspondingly, the spectacle lens obtained from this method cycle had an improved smoothness.

As a comparative example, a commercially available spectacle lens, which was structurally identical in respect of its substrate to the plastic spectacle lens of the exemplary embodiment, but which was not provided with a corresponding functional coating, was used.

Here again, the measurement of the dynamic coefficients of friction was carried out with tangential speeds of 0.01 m/s, 0.07 m/s, 0.15 m/s and 0.20 m/s, as described in connection with the exemplary embodiment.

The dynamic coefficients of friction determined in this way gave an HGK of 0.473 according to formula (XI) and an R_HGK of 1.77 according to formula (XII).

The spectacle lens of the comparative example therefore did not satisfy the quality requirements in respect of smoothness.

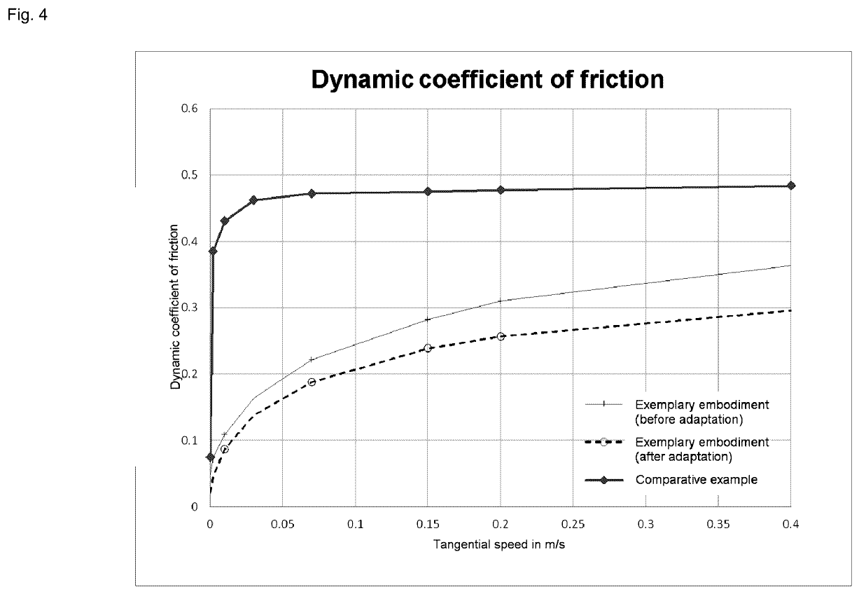

As may be seen from FIG. 4, the speed-dependent dynamic coefficient of friction in the case of the coated plastic spectacle lenses of the exemplary embodiment is comparatively low. With an increasing tangential speed, only a minor rise in the dynamic coefficient of friction is to be observed. The spectacle lens according to the invention therefore allows particularly easy wiping with little exertion of force. By contrast, the dynamic coefficient of friction is increased significantly in the case of the spectacle lens of the comparative example.

### LIST OF REFERENCE SIGNS

2 control unit
10 coating apparatus
12 emission device
14 shutter device
16 measurement sensor
18 holding device
20 arithmetic unit
22 memory unit
24 communication unit
26 input unit
30 substrate
40, 42, 42′ connection
S100 step (a)
S102 step (b)
S104 step (c)
S106 step (d)
S108 step (e)
S110 step (f)
S112 step (g)

1. A measurement method for determining the smoothness of a spectacle lens with the aid of a rheometer by determining dynamic coefficients of friction in relation to a microfiber cloth, which describes a circular path around the center of the spectacle lens, the determination of dynamic coefficients of friction being carried out with speeds in the range of from 0.005 m/s to 0.4 m/s tangentially with respect to the described circular path and tangentially with respect to the surface of the spectacle lens,
wherein the smoothness of the spectacle lens is expressed by a haptic smoothness coefficient HGK, calculated as a weighted average dynamic coefficient of friction from at least two dynamic coefficients of friction determined with different tangential speeds.

2. The measurement method as claimed in claim 1, wherein dynamic coefficients of friction which are determined with tangential speeds of 0.20 m/s, 0.15 m/s and 0.07 m/s are entered into the calculation of the haptic smoothness coefficient HGK.

3. The measurement method as claimed in claim 2, wherein the haptic smoothness coefficient HGK is calculated with the aid of the following formula (XI):
$$HGK = 0.5 \times {μ}_{d} ( 0.2 m / s ) + 0.35 \times {μ}_{d} ( 0.15 m / s ) + 0.15 \times {μ}_{d} ( 0.07 m / s ) \qquad ( XI )$$
where μ_{d}(0.20 m/s) is the dynamic coefficient of friction determined with a tangential speed of 0.20 m/s, μ_{d}(0.15 m/s) is the dynamic coefficient of friction determined with a tangential speed of 0.15 m/s and μ_{d}(0.07 m/s) is the dynamic coefficient of friction determined with a tangential speed of 0.07 m/s.

4. The measurement method as claimed in claim 3, wherein the dynamic coefficient of friction is additionally determined with a tangential speed of 0.01 m/s, and this is entered into the calculation of a haptic smoothness coefficient R_HGK with the aid of the following formula (XII):
$$R\_HGK = HGK + 3 \times {μ}_{d} ( 0.01 m / s ) \qquad ( XII )$$
where μ_{d}(0.01 m/s) is the dynamic coefficient of friction determined with a tangential speed of 0.01 m/s.

5. A spectacle lens having a substrate and a functional coating arranged as the outermost layer on the substrate,
wherein the functional coating imparts to the spectacle lens a haptic smoothness coefficient HGK of at most 0.28, preferentially at most 0.25, determined in accordance with the measurement method as claimed in claim 3, and/or a haptic smoothness coefficient R_HGK of at most 0.85, preferentially at most 0.80, determined in accordance with the measurement method as claimed in claim 4.

6. The spectacle lens as claimed in claim 5, wherein the functional coating is formed from a compound (1) comprising a perfluorinated hydrocarbon radical, which has one or more etheric oxygen atoms, and further comprising at least one silyl group, which may be substituted with one or more hydrolysable groups, with the proviso that the compound (1) contains at least two hydrolysable groups and is represented by the following formula (A): 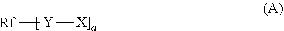
where a is 1 or 2, Rf denotes a perfluoroalkyl ether radical if a is 1, or a perfluoroalkylene ether radical if a is 2, X denotes a radical having at least one silyl group, which may be substituted with one or more hydrolysable groups, and Y denotes an optional radical which links the perfluoroalkyl(ene) ether radical Rf and the radical X to one another.

7. The spectacle lens as claimed in claim 6, wherein the hydrolysable groups are respectively selected independently of one another from the group consisting of an alkoxy group having 1 to 10 carbon atoms, an alkoxyalkoxy group having 2 to 10 carbon atoms, an alkenyloxy group having 2 to 10 carbon atoms, an acyloxy group having 1 to 10 carbon atoms, an amino group and a halogen atom.

8. The spectacle lens as claimed in claim 6, wherein the hydrolysable groups are respectively selected independently of one another from the group consisting of a methoxy group, an ethoxy group, an isopropenoxy group and a chlorine atom.

9. The spectacle lens as claimed in claim 6, wherein the compound (1) represented by formula (A) is trimethoxysilane, which comprises a perfluoroalkyl ether radical.

10. The spectacle lens as claimed in claim 5, wherein the thickness of the functional coating lies in a range of from 1 nm to 100 nm.

11. The spectacle lens as claimed in claim 5, wherein at least one further layer selected from the group consisting of a priming layer, a hard layer and an interference/antireflection layer, in the order specified starting from the surface of the substrate, is arranged between the substrate and the functional coating arranged as the outermost layer on the substrate.

12. A method for producing a spectacle lens, in particular for producing the spectacle lens as claimed in claim 5, comprising the following steps (a) to (f):
(a) adjusting coating parameters on a coating apparatus,
(b) providing a substrate,
(c) inserting the substrate into the coating apparatus,
(d) providing the substrate with a functional coating in the coating apparatus, so that a spectacle lens having a substrate and a functional coating arranged as the outermost layer on the substrate is obtained,
(e) removing the spectacle lens from the coating apparatus, and
(f) determining the haptic smoothness coefficient HGK in accordance with the measurement method as claimed in one of claims 1 to 3 and/or the haptic smoothness coefficient R_HGK in accordance with the measurement method as claimed in claim 4.

13. The method as claimed in claim 12, further comprising the following step (g) after step (f):
(g) ascertaining a deviation of the haptic smoothness coefficient HGK and/or of the haptic smoothness coefficient R_HGK from a previously established setpoint value, in order to adapt the coating parameters in step (a) on the basis of the ascertained deviation if appropriate.

14. The method as claimed in claim 12, wherein the substrate is provided with a functional coating in the coating apparatus in step (d) by evaporation using a source containing the compound (1).

15. The method as claimed in claim 14, wherein the source containing the compound (1) is a tablet or pellet, which contains the compound (1) in bound form.

16. The method as claimed in claim 14, wherein the evaporation is carried out with an evaporation rate in a range of from 0.05 nm/s to 3 nm/s.

17. The method as claimed in claim 14, wherein the evaporation is carried out with the aid of a thermal evaporator.
